(19) United States
(12) Patent Application Publication
(10) Pub. No.: US 2016/0254824 A1
(43) Pub. Date: Sep. 1, 2016

(54) DETERMINING COMPRESSION TECHNIQUES TO APPLY TO DOCUMENTS

(71) Applicant: LONGSAND LIMITED, Cambridge, Cambridgeshire (GB)

(72) Inventor: Sean Blanchflower, Cambridge (GB)

(21) Appl. No.: 15/033,565

(22) PCT Filed: Nov. 26, 2013
(86) PCT No.: PCT/EP2013/074780

§ 371 Date: Apr. 29, 2016

(51) Int. Cl. H03M 7/30

(52) U.S. Cl. CPC H03M 7/6094

(57) ABSTRACT

Examples of determining compression techniques to apply to documents are disclosed. In one example implementation according to aspects of the present disclosure, a method may include analyzing, by the computing system, at least a subset of a plurality of documents received by the computing system to determine document characteristics relating to the at least the subset of the plurality of documents. The method may also include determining, by the computing system, which of a plurality of compression techniques to apply to the plurality of documents based on the determined document characteristics.

### BACKGROUND

Users of electronic devices such as personal computers, smart phones, and tablets generate ever increasing amounts of data. Often, the data are stored on servers accessible via the Internet or another suitable network. Users may wish to access the data with varying amounts of frequency depending on the various types of data stored.

### BRIEF DESCRIPTION OF THE DRAWINGS

The following detailed description references the drawings, in which:

FIG. 1 illustrates a block diagram of determining compression techniques to apply to documents according to examples of the present disclosure;

FIG. 2 illustrates a block diagram of a computing system for determining compression techniques to apply to documents according to examples of the present disclosure;

FIG. 3 illustrates a flow diagram of a method for determining compression techniques to apply to documents according to examples of the present disclosure; and

FIG. 4 illustrates a flow diagram of a method for determining compression techniques to apply to documents according to examples of the present disclosure.

### DETAILED DESCRIPTION

Systems that perform indexing of documents or content for retrieval or archiving purposes store the content of a large amount of data. For example, a document indexing system may index hundreds of thousands or millions of documents, which my represent tens, hundreds, or even thousands of gigabytes of data. Users of computing systems may wish to access the data stored on the systems that perform the indexing and archiving.

The constraints on storage within such systems are frequently the determining factor on both the cost and the scaling of such systems and any reduction in storage can be of great benefit. For example, in some situations it is beneficial to perform standard compression algorithms on the content in order to reduce the amount of storage space needed. However, this practice generally has a negative effect on retrieval performance because the compressed data must be uncompressed when it is retrieved.

Moreover, for small documents, the compressed form can in fact be larger than the original. For example, if a system is indexing and storing millions of tweets, status updates, or other similar small pieces of data, it may not be beneficial to compress the individual data because doing so would result in a larger compressed file than the original. In contrast, very large files may benefit from aggressive compression techniques in order to reduce them to more manageable file sizes.

Previously, these systems that perform indexing and archiving of documents rely on applying a single compression technique to all documents. This leads to inefficiencies in both storage and retrieval. Some systems implement no compression if high efficiency is desired, while some systems implement aggressive compression if storage space is at a premium. The use of a single compression technique reduces retrieval performance for some documents and increases storage requirements for others.

Various embodiments will be described below by referring to several examples of determining compression techniques to apply to documents. Documents may be received by a computing system and subsequently analyzed. Using the analysis, the computing system may determine which of a plurality of compression techniques to apply to each of the documents. The documents may then be compressed according to the determined compression technique.

In some implementations, determining compression techniques to apply to a collection of documents reduces the amount of storage necessary in document storage and indexing databases. Determining compression techniques to apply to a collection of documents also increases system response time and performance by optimizing document compression. Moreover, the amount of storage needed for document indexing and storage may be balanced against system performance concerns. These and other advantages will be apparent from the description that follows.

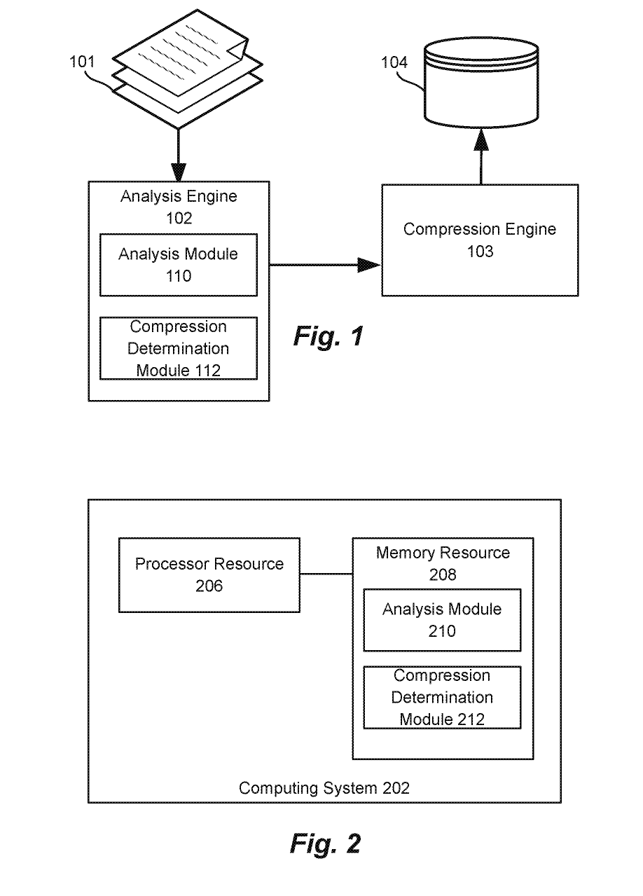

FIG. 1 illustrates a block diagram of determining compression techniques to apply to documents according to examples of the present disclosure. In this example, a corpus or collection of documents such as plurality of documents 101 is stored, for example, in a document repository or other suitable document storage solution for storing documents. It should be understood that, although the term document is used throughout, it includes files, data, documents, and other similar information. The use of the term documents should not therefore be limiting.

FIG. 1 may include a collection of documents 101, an analysis engine 102, a compression engine 103, and a database 104. It should be understood that the analysis engine 102 and/or the compression engine 103 may include any appropriate type of computing system or device or subcomponent thereof, including for example smartphones, tablets, desktops, laptops, workstations, servers, smart monitors, smart televisions, digital signage, scientific instruments, retail point of sale devices, video walls, imaging devices, peripherals, or the like. The analysis engine 102 and/or the compression engine 103 may also include electrical circuitry (such as part of a larger computing device). In another example, the analysis engine 102 and/or the compression engine 103 may be machine executable instructions stored on a non-transitory tangible computer-readable storage medium.

The collection of documents 101 are received by an analysis engine 102 such as via a network or through other appropriate communicative processes. The analysis engine 102 analyzes the plurality of documents 101 received from, for example, a document repository. The analysis engine 102 may include an analysis module 110 to determine document characteristics about the collection of documents 101 and/or about individual documents or a subset of documents within the collection of documents 101. These document characteristics may include, for example, a file name, a file extension, a document type, frequency of access to a document, a document priority, a file size, a title, an author, and/or other types of document characteristics.

The analysis engine 102 may also include a compression determination module 112 to determine which of a plurality of compression techniques to apply to each of the documents in the collection of documents 101. The determination may be based on one or more of the document characteristics identified by the analysis engine 110, including file name, file extension, document type, frequency of access to each document, document priority, file size, title, author, and/or other types of document characteristics.

Once the compression determination module 112 of the analysis engine 102 determines which of the plurality of compression techniques to apply to each document of the collection of documents 101, a compression engine 103 compresses each of the plurality of documents using the appropriate compression technique determined by the compression determination module 112 of the analysis engine. Once the compression determination module 112 compresses a document, the document may be stored in a document database 104.

In one example, such as shown in FIG. 1, the analysis engine 102, the compression engine 103, and the document database 104 may all be separate computing systems. However, in another example, any of the components may be combined such that a single computing system performs one or more of the functions described.

It should be further understood that the analysis module and/or the compression determination module 112 described herein may be a combination of hardware and programming. The programming may be processor executable instructions stored on a tangible memory resource (such as memory resource 208 of FIG. 2), and the hardware may include a processing resource (such as processing resource 206 of FIG. 2) for executing those instructions. Thus the memory resource can be said to store program instructions that when executed by the processing resource implement the modules described herein. In another example, the modules described may exist as electronic circuitry inside of a larger computing system.

FIG. 2 illustrates a block diagram of a computing system 202 for determining compression techniques to apply to documents according to examples of the present disclosure. It should be understood that the computing system 202 may include any appropriate type of computing system or device, including for example smartphones, tablets, desktops, laptops, workstations, servers, smart monitors, smart televisions, digital signage, scientific instruments, retail point of sale devices, video walls, imaging devices, peripherals, or the like.

The computing system 202 may include a processing resource 206 that may be configured to process instruction& The instructions may be stored on a non-transitory tangible computer-readable storage medium, such as memory resource 208, or on a separate device (not shown), or on any other type of volatile or non-volatile memory that stores instructions to cause a programmable processor to perform the techniques described herein. Alternatively or additionally, the computing system 202 may include dedicated hardware, such as one or more integrated circuits, Application Specific Integrated Circuits (ASICs), Application Specific Special Processors (ASSPs), Field Programmable Gate Arrays (FPGAs), or any combination of the foregoing examples of dedicated hardware, for performing the techniques described herein. In some implementations, multiple processors may be used, as appropriate, along with multiple memories and/or types of memory.

In addition to the processing resource 206 and the memory resource 208, the computing system 202 may include an analysis module 210 and a compression determination module 212. In one example, the modules described herein may be a combination of hardware and programming. The programming may be processor executable instructions stored on a tangible memory resource such as memory resource 208, and the hardware may include processing resource 206 for executing those instructions. Thus memory resource 208 can be said to store program instructions that when executed by the processing resource 206 implement the modules described herein. Other modules may also be utilized as will be discussed further below in other examples.

The analysis module 210 analyzes documents to determine document characteristics relating to the analyzed documents. In one example, the computing system 202 may receive data in the form of documents from, for example, a document repository, which may be stored on or generated at another computing system. The documents may be analyzed by the analysis module 210 to determine document characteristics relating to the documents. For example, the document characteristics may include file name, file extension, document type, frequency of access to each document, document priority, file size, title, author, and/or other types of document characteristics. The analysis module 212 may also group or sort documents by document characteristics, such as by grouping files of certain types, sizes, frequency of access, etc. together.

The compression determination module 212 determines which of a plurality of compression techniques to apply to each of the received documents. The compression determination module 212 may base the determination of which compression technique to apply to each document in whole or in part on the document characteristics determined by the analysis module. For example, the compression determination module 212 may determine to apply the different compression techniques based on file size, frequency of access, file type, etc.

In one example, the compression determination module 212 may determine to apply a first compression technique to documents that are frequently accessed while applying a second, more aggressive, compression technique to documents that are less frequently accessed. Similarly, the compression determination module 212 may determine to apply a first compression technique to documents that are small in size while applying a second, more aggressive, compression technique to documents that are larger in size.

Moreover, the compression determination module 212 may determine to apply compression techniques to groups of documents rather than individual documents. For example, the compression determination module 212 may determine to apply an aggressive compression technique to documents created before a certain date, while applying less aggressive compression techniques to documents created after that date. Or the compression determination module 212 may determine to apply a first compression technique to documents of a first type, a second compression technique to documents of a second type, and a third compression technique to documents of a third type.

Additional modules may also be utilized in examples. For instance, the computing system 202 may include a document receiving module in one example. The document receiving module receives documents (i.e., data) from, for example, a document repository or database. The received documents may be loaded into a local data store (not shown). In one example, the computing system 202 also includes a compression module for compressing the documents according to the compression technique determined by the compression determination module 212.

The computing system 202 may also include an historical compression profile generating module which generates an historical compression profile based in part on the analyzing the plurality of documents and based in part on the determining which of the plurality of compression techniques to apply to each of the plurality of documents. The compression determination module 212 may utilize the historical compression profile to determine which of the plurality of compression techniques to apply to each document. For example, if certain documents are historically compressed with one type of compression technique, the compression determination module 212 may determine to compress similar documents using the same technique in the future. These and other modules maybe implemented in any suitable combination in various examples.

Although not illustrated, in some embodiments the computing system 202 may also include a data store, which may be one or more electronic or mechanical data storage devices, such as hard disk drives, solid state drives, magnetic memory devices, and the like. The data store may be contained on a single computing device or distributed across a collection of computing devices. The data store may include one or more databases, for which the computing system 202 processes transactions. The data store 206 may also store documents received from a document repository and/or documents compressed by the computing system 202.

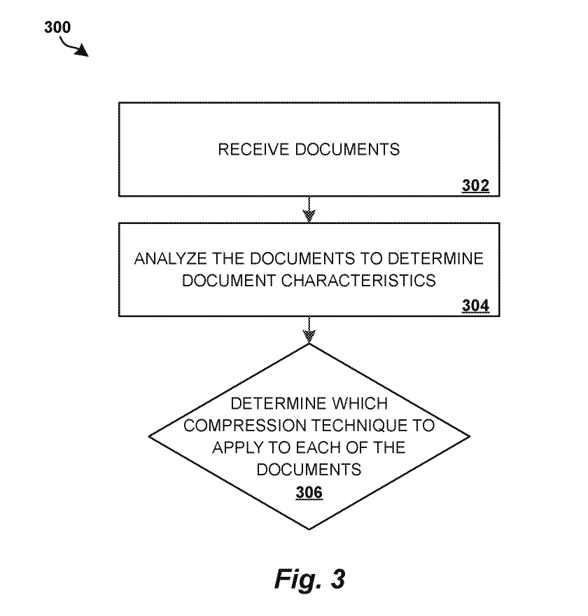

FIG. 3 illustrates a flow diagram of a method 300 for determining compression techniques to apply to documents according to examples of the present disclosure. The method 300 may be executed by a computing system or a computing device such as computing device 102 of FIG. 1 and computing system 202 of FIG. 2. In one example, the method 300 may include: receiving documents (block 302); analyzing the documents to determine document characteristics (block 304); and determining which compression technique to apply to each of the documents (block 306).

At block 302, the method 300 may include receiving documents. In one example, a computing system (e.g., computing system 202 of FIG. 2) receives a plurality of documents. The documents may be received from a document repository (or multiple document repositories). The plurality of documents may include anywhere from a few documents to millions of documents. The documents may vary in type and size, although many of the documents may be of the same type or of similar size. It should be understood that the documents may have one or more document characteristics associated with each of the documents. These document characteristics may include, for example, a file name, a file extension, a document type, frequency of access to a document, a document priority, a file size, a title, an author, and/or other types of document characteristics.

The documents may be received by the computing system via a network or other communicative methods. The documents may also be previously stored on the computing system directly or indirectly via an attached database having the document repository. Once the computing system receives the plurality of documents, the method 300 continues to block 304.

At block 304, the method 300 may include analyzing the documents to determine document characteristics. In one example, a computing system analyzes (e.g., through the analysis module 210 of the computing system 202 of FIG. 2) at least a subset of the plurality of documents to determine document characteristics relating to each of the at least the subset of the plurality of documents. The analysis may include determining the file name, file extension, document type, frequency of access to each document, document priority, file size, title, author, and/or other types of document characteristics for each document. In one example, the analysis may include grouping documents by similar document types, by similar frequency of access to each document, or by other document characteristics. The method 300 then continues to block 306.

At block 306, the method 300 may include determining which compression technique to apply to each of the documents. For example, a computing system determines (e.g., through the compression determination module 212 of the computing system 202 of FIG. 2) which of a plurality of compression techniques to apply to each of the plurality of documents based on the determined document characteristics.

In one example, the computing system may determine (e.g., through the compression determination module 212 of the computing system 202 of FIG. 2) to apply a first compression technique to documents of one type while determining to apply a second compression technique to documents of another type. The first compression technique may be a low-compression technique suited for frequently accessed or small documents. In contrast, the second compression technique may be a high-compression technique suited for infrequently accessed or very large documents. In this way, the computing system experiences increased performance by being able to decompress frequently accessed documents quickly when called to do so while saving storage space by compressing infrequently accessed documents to a greater extent.

Additionally, the computing system may determine (e.g., through the compression determination module 212 of the computing system 202 of FIG. 2) which of the plurality of compression techniques to apply to each of the plurality of documents based on (or based in apart on) the frequency with which the document (or other similar documents) is accessed. For example, if the system stores social media updates such as status messages or tweets, these types of documents may be infrequently accessed and thus may be compressed to a greater extent, while documents such as user profiles, which may be more frequently accessed, may not be as highly compressed.

Once the computing system determines which compression technique to apply to each of the documents, the method 300 may include compressing the documents using the determined compression technique. In one example, the computing system compresses each of the plurality of documents using the determined one of the plurality of compression techniques. This may also include causing another computing system, or a component of the computing system, to compress the documents, rather than the computing system doing it directly.

Additional processes also may be included. For example, the method 300 may include the computing system generating an historical compression profile. The historical compression profile may be based in part on the analyzing at least the subset of the plurality of documents and may be further based in part on the determining which of the plurality of compression techniques to apply to each of the plurality of documents. The computing system then uses the historical compression profile to determine which of the plurality of compression techniques to apply to each of the documents. Using the historical compression profile enables the computing system to “learn” past behaviors and patterns of documents and of the compression techniques determined to apply to the various documents.

It should be understood that the processes depicted in FIG. 3 represent illustrations, and that other processes may be added or existing processes may be removed, modified, or rearranged without departing from the scope and spirit of the present disclosure.

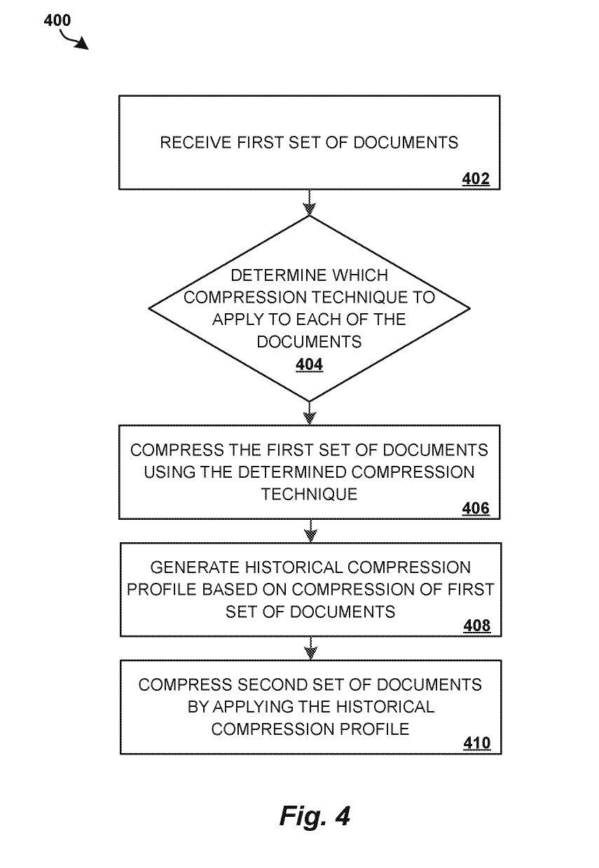

FIG. 4 illustrates a flow diagram of a method 400 for determining compression techniques to apply to documents according to examples of the present disclosure. The method 400 may be executed by a computing system or a computing device such as computing device 102 of FIG. 1 and computing system 202 of FIG. 2. In one example, method 400 may include: receiving a first set of documents (block 402); determining which compression technique to apply to each of the documents (block 404); compressing the first set of documents using the determined compression technique (block 406); generating an historical compression profile based on the compression of the first set of documents (block 408); and compressing the second set of documents by applying the historical compression profile (block 410).

At block 402, the method 400 may include receiving a first set of documents. In one example, a computing system receives (e.g., at the computing system 202 of FIG. 2) a plurality of documents from a document repository or other suitable storage location of the documents. Once the documents are received, the method 400 continues to block 404.

At block 404, the method 400 may include determining which compression technique to apply to each of the documents. In an example, the computing system determines (e.g., through the compression determination module 210 of the computing system 202 of FIG. 2) which of a plurality of compression techniques to apply to each of the plurality of documents. The compression techniques vary and may be suitable for compressing documents depending on the document's type, size, frequency of access, and/or other characteristics, which may be determined during an analysis of the documents or which may be included in document metadata associated with the documents.

In one example, the plurality of documents received may include a document of a first type and a document of a second type. In this case, determining which of the plurality of compression techniques to apply to each of the plurality of documents includes determining to apply a first compression technique to the document of the first type and determining to apply a second compression technique to the document of the second type.

Additionally, a second document of the first type may be compressed using the same compression technique that was determined to apply to the first document of the first time. That is, in an example where the document of the first type was an audio file that was compressed using an audio compression technique, the second document that is also an audio document may likewise be compressed using the same audio compression technique. Similarly, a second document of the second type may be compressed using the same compression technique that was determined to apply to the second document of the second type. The method 400 then continues to block 406.

At block 406, the method 400 may include compressing the first set of documents using the determined compression technique. For example, the computer system compresses (e.g., through the compression engine 103 of the FIG. 1) each of the plurality of documents using the determined compression technique for each of the plurality of documents. In another example, the computing system may cause another device or computing system to perform the compressing the first set of documents. In that case, the documents may be associated with or otherwise assigned a determined compression technique. The method 400 continues to block 408.

At block 408, the method 400 may include generating an historical compression profile based on the compression of the first set of documents. In an example, the computer system (e.g., the computing system 202 of FIG. 2) generates an historical compression profile based on the determination of which of the plurality of compression techniques to apply to each of the plurality of documents. The computing system may also generate the historical compression profile based in part on analyzing the plurality of documents and based in part on the determining which of the plurality of compression techniques to apply to each of the plurality of documents. The historical compression profile may also be previously created and loaded onto the computing system, such as from another similar computing system, or it may be configured manually by a system administrator. Once the historical compression profile is created, the method 400 may continue to block 410.

At block 410, the method 400 may include compressing the second set of documents by applying the historical compression profile. For example, the computer system compresses (e.g., through the compression engine 103 of the FIG. 1) each of a second plurality of documents by applying the historical compression profile to the second plurality of documents to determine which of the plurality of compression techniques to apply to each of the second plurality of documents. In this way, documents may be compressed using similar techniques as were applied to documents previously compressed. This may reduce the time and system resources needed to determine which compression techniques to apply to each type of document. It should be understood that the compression may occur on the same or on a separate communicatively coupled computing system or other suitable device or hardware and/or programming.

Additional processes also may be included, and it should be understood that the processes depicted in FIG. 4 represent illustrations, and that other processes may be added or existing processes may be removed, modified, or rearranged without departing from the scope and spirit of the present disclosure.

It should be emphasized that the above-described examples are merely possible examples of implementations and set forth for a clear understanding of the present disclosure. Many variations and modifications may be made to the above-described examples without departing substantially from the spirit and principles of the present disclosure. Further, the scope of the present disclosure is intended to cover any and all appropriate combinations and sub-combinations of all elements, features, and aspects discussed above. All such appropriate modifications and variations are intended to be included within the scope of the present disclosure, and all possible claims to individual aspects or combinations of elements or steps are intended to be supported by the present disclosure.

What is claimed is:

1. A method comprising:
analyzing, by the computing system, at least a subset of a plurality of documents received by the computing system to determine document characteristics relating to the at least the subset of the plurality of documents; and
determining, by the computing system, which of a plurality of compression techniques to apply to the plurality of documents based on the determined document characteristics.

2. The method of claim 1, wherein the determined document characteristics are selected from the group consisting of a file name, a file extension, a document type, a frequency of document access, a document priority, a file size, a title, and an author.

3. The method of claim 1, further comprising:
compressing, by the computing system, the plurality of documents using the determined one of the plurality of compression techniques.

4. The method of claim 1, further comprising:
generating, by the computing system, an historical compression profile based in part on the analyzing at least the subset of the plurality of documents and based in part on the determining which of the plurality of compression techniques to apply to the plurality of documents.

5. The method of claim 4, further comprising:
receiving, by the computing system, a second plurality of documents; and
determining, by the computing system, which of the plurality of compression techniques to apply to the second plurality of documents based on the historical compression profile.

6. A computing system comprising:
a processing resource;
a memory resource;
an analysis module executable by the processing resource to analyze a plurality of documents to determine document characteristics relating to the plurality of documents; and
a compression determination module executable by the processing resource to determine which of the plurality of compression techniques to apply to the plurality of documents based on the determined document characteristics.

7. The computing system of claim 6, further comprising:
a compression module to apply the determined compression techniques to the documents.

8. The computing system of claim 6, further comprising:
an historical compression profile generating module executable by the processing resource to generate an historical compression profile based in part on the analyzing the plurality of documents and based in part on the determining which of the plurality of compression techniques to apply to the plurality of documents.

9. The computing system of claim 8, wherein the compression determination module determines which of the plurality of compression techniques to apply to the plurality of documents based in part on the historical compression profile.

10. The computing system of claim 6, wherein determining which of the plurality of compression techniques to apply to the plurality of documents is based on a frequency of document access.

11. A non-transitory computer-readable storage medium storing instructions that, when executed by a processor, cause the processor to:
receive a plurality of documents;
determine which of a plurality of compression techniques to apply to the plurality of documents;
compress the plurality of documents using the determined compression technique for the plurality of documents;
generate an historical compression profile based on the determination of which of the plurality of compression techniques to apply of the plurality of documents; and
compress a second plurality of documents by applying the historical compression profile to the second plurality of documents to determine which of the plurality of compression techniques to apply to the second plurality of documents.

12. The computer-readable storage medium of claim 11, wherein the plurality of compression techniques differ.

13. The computer-readable storage medium of claim 11, wherein the plurality of documents includes a document of a first type and a document of a second type, and wherein determining, by the computing system, which of the plurality of compression techniques to apply to each of the plurality of documents includes determining to apply a first compression technique to the document of the first type and determining to apply a second compression technique to the document of the second type.

14. The computer-readable storage medium of claim 13, wherein a second document of the first type is compressed using the same compression technique determined to apply to the document of the first type, and wherein a second document of the second type is compressed using the same compression technique determined to apply to the document of the second type.

15. The computer-readable storage medium of claim 11, wherein determining which of the plurality of compression techniques to apply to the plurality of documents is based on the frequency of document access.
